(19) United States
(12) Patent Application Publication
(10) Pub. No.: US 2012/0289050 A1
(43) Pub. Date: Nov. 15, 2012

(54) METHOD OF ETCHING TRENCHES IN A SEMICONDUCTOR SUBSTRATE UTILIZING PULSED AND FLUOROCARBON-FREE PLASMA

(76) Inventors: Chang-Ming Wu, New Taipei City (TW); Yi-Nan Chen, Taipei City (TW); Hsien-Wen Liu, Taoyuan County (TW)

(21) Appl. No.: 13/103,113

(22) Filed: May 9, 2011

(51) Int. Cl. H01L 21/3065

(52) U.S. Cl. 438/702; 257/E21.218

(57) ABSTRACT

A method of etching trenches in a semiconductor substrate. A patterned hard mask is formed over a semiconductor substrate. Using the patterned hard mask as an etching mask, a plasma etching process is then carried out to etch trenches into the semiconductor substrate not covered by the patterned hard mask, wherein the plasma etching process employs a fluorocarbon-free plasma etching chemistry and is performed under a plasma pulse output mode.

### BACKGROUND OF THE INVENTION

1. Field of the Invention

The present invention relates to a method of plasma etching. In particular, the present invention relates to a method of etching trenches in a semiconductor substrate utilizing pulsed and fluorocarbon-free plasma.

2. Description of the Prior Art

In the fabrication of integrated circuitry, numerous devices are packed into a small area of a semiconductor substrate to create an integrated circuit. As the size of integrated circuits shrinks, the devices that make up the circuits are positioned closer and closer to each other. Many of the individual devices are electrically isolated by a trench isolation structure, which is an integral part of semiconductor device design for preventing unwanted electrical coupling between adjacent components and devices.

Conventionally, the trench isolation structure is formed by first etching trenches into a semiconductor substrate and then filling the trenches with insulative material. As the density of components on the semiconductor substrate increases, the widths of the trenches have decreased. Further, the depths of the trenches have tended to increase. The dense trench pattern (usually in a densely packed array region) and isolated trench pattern (usually in a peripheral region) usually lead to micro-loading effect during plasma etching. As known in the art, the etching rate of the silicon substrate is faster when etching the isolated trench pattern than that for etching dense trench pattern. The difference in etching rate results in a deeper trench in a peripheral region. After filling the insulative material into the etched trenches, the thicker dielectric film in the deeper trench may induce higher stress. The deeper trench produce may also result in irregular topography that may adversely affect the overlay accuracy during a lithographic process.

Typically, a fluorocarbon-based plasma chemistry containing fluorocarbon (CHₓF_{y}) is utilized for etching trench in a silicon substrate. The fluorocarbon can maintain a vertically straight sidewall profile in the etched trenches without significant bowing at the bottom of each trench. However, the polymer residues generated from the reaction between the fluorocarbon and the plasma also causes masking in the isolated region such as peripheral region during plasma etching. Further, the conventional plasma etching method has poor mask selectivity. In the manufacture of high density semiconductor device such as dynamic random access memory (DRAM) array, it is important to maintain the integrity of the post-etch profile of the hard mask.

Accordingly, a need exits in this industry for developing improved etching chemistries and an improved plasma etching method, which enable trenches to be etched into silicon, for example in the fabrication of trench isolation, with improved sidewall profile, increased mask selectivity, and reduced micro-loading effect.

### SUMMARY OF THE INVENTION

It is one objective of the present invention to provide an improved method of plasma etching a substrate with increased mask selectivity, thereby maintaining the integrity of the post-etch profile of the hard mask.

It is another objective of the present invention to provide an improved method of etching trenches in a substrate by utilizing pulsed and fluorocarbon-free plasma to thereby form a vertically straight sidewall profile, meanwhile the micro-loading effect can be eliminated.

To these ends, according to one aspect of the present invention, there is provided a method of etching trenches in a semiconductor substrate. A patterned hard mask is formed over a semiconductor substrate. Using the patterned hard mask as an etching mask, a plasma etching process is then carried out to etch trenches into the semiconductor substrate not covered by the patterned hard mask, wherein the plasma etching process employs a fluorocarbon-free plasma etching chemistry and is performed under a plasma pulse output mode.

According to one embodiment of this invention, the fluorocarbon-free plasma etching chemistry comprises an etching gas including SF₆ or NF₃, a passivation gas including O₂, HBr or carbonyl sulfide (COS), and a dilute gas including helium (He), nitrogen (N₂) or argon (Ar).

According to one embodiment of this invention, the plasma pulse output mode comprises a period T of one single duty cycle having an output ON period t₁ and an output OFF period t₂, and thus generating plasma periodically. Preferably, a percentage of the output ON period t₁ relative to the period T is in a range from 20% to 80%.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIGS. 1-2 are schematic, cross-sectional diagrams illustrating a method of forming a trench isolation structures in a semiconductor substrate in accordance with one embodiment of this invention; and

FIG. 3 is a schematic diagram showing a plasma pulse output mode in accordance with the embodiment of the invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description, reference is made to the accompanying drawings, which form a part hereof, and in which is shown by way of illustration specific examples in which the embodiments may be practiced. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

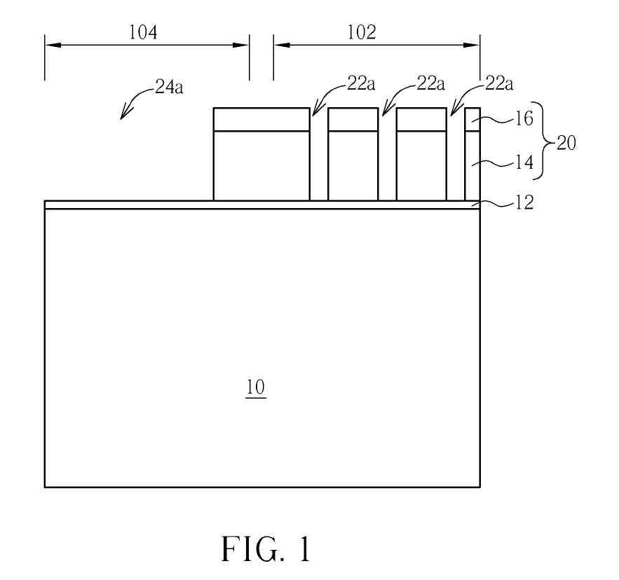

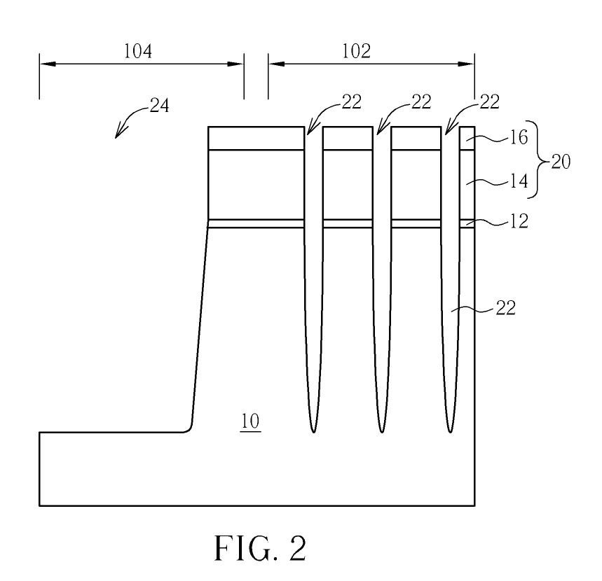

FIGS. 1-2 are schematic, cross-sectional diagrams illustrating a method of forming a trench isolation structures in a semiconductor substrate in accordance with one embodiment of this invention. As shown in FIG. 1, a semiconductor substrate 10 is provided. According to this embodiment, the semiconductor substrate 10 may be a silicon substrate. A patterned hard mask 20 is formed on a main surface of the semiconductor substrate 10. The patterned hard mask 20 defines a dense trench pattern 22a within a memory array region 102 and an isolated, peripheral trench pattern 24a within a peripheral region 104, which are to be transferred to the semiconductor substrate 10.

The patterned hard mask 20 may comprise a film stack including but not limited to a first hard mask layer 14 and a second hard mask layer 16 overlying the first hard mask layer 14. For example, the first hard mask layer 14 may be composed of polysilicon and may have a thickness of about 80 nm, and the second hard mask layer 16 may be composed of silicon oxide and may have a thickness of about 80 nm. According to this embodiment, a pad oxide layer 12 may be formed between the patterned hard mask 20 and the semiconductor substrate 10.

As shown in FIG. 2, using the patterned hard mask 20 as an etching mask, an anisotropic dry etching process is carried out to etch the exposed pad oxide layer 12 and the semiconductor substrate 10, to thereby form a plurality of dense trenches 22 within the memory array region 102 and at least one trench 24 within the peripheral region 104. After the formation of the dense trenches 22 and trench 24, a trench filler (not shown) such as HDP oxide or the like is deposited into the dense trenches 22 and trench 24. The semiconductor substrate or the entire wafer is then subjected to a chemical mechanical polishing (CMP) to remove the excess trench filler thereby forming trench isolation structures.

According to this embodiment, the depth of the trench 24 is substantially equal to that of the trench 22 such that the micro-loading effect is eliminated. In other embodiments, the depth of the trench 24 may be shallower than that of the trench 22. Therefore, according to the embodiments of this invention, the depth of the trench 24 within the peripheral region 104 is controllable. Within the memory array region 102, each of the dense trenches 22 has a straight sidewall profile. Further, no polymer residue is observed within the peripheral region 104 during the etching of the trench 24 such that the masking phenomenon can be avoided. The integrity of the post-etch profile of the hard mask 20 is well maintained due to increased mask selectivity.

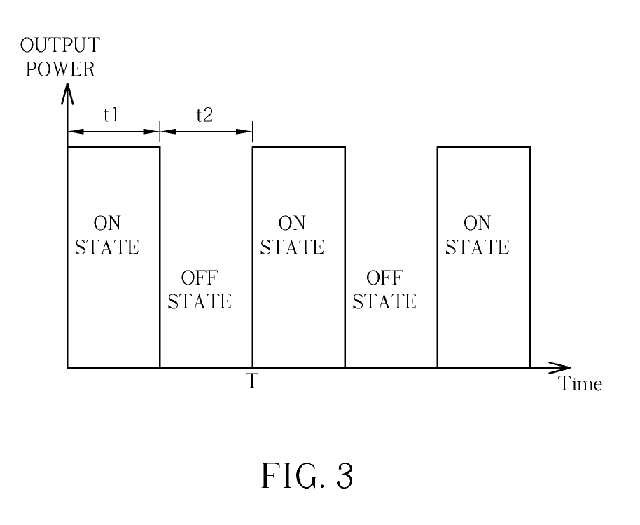

According to the embodiment of this invention, the aforesaid anisotropic dry etching process utilizes pulsed and fluorocarbon-free plasma. FIG. 3 is a schematic diagram showing a plasma pulse output mode in accordance with the embodiment of the invention. As shown in FIG. 3, an x-axis represents a period of time required from a start to an end of an etching process, and a y-axis represents an output power of an RF power source (or a bias power in voltage). According to the embodiment of this invention, the RF power source outputs RF power of, for example, 300 W-1000 W, in a pulse mode. That is, during an etching process, the RF power source outputs RF power in an intermittent, non-continuous mode for excitation of an etching gas. A period T of one single duty cycle includes an output ON period (or etching period) t₁ and an output OFF period (or passivation period) t₂, and thus the generation of plasma is periodic. In the output ON period, the plasma etches a material layer on a substrate surface. In the output OFF period, the RF power source disables excitation and plasma output. Moreover, a percentage of the output ON period t₁ relative to the whole period T, which is also referred to as a “duty cycle”, can be controlled in a range from 20% to 80%.

In combination with the plasma pulse output mode, a fluorocarbon-free plasma etching chemistry for etching the silicon substrate with high mask selectivity is employed. According to the embodiment of this invention, the fluorocarbon-free plasma etching chemistry may include but not limited to an etching gas such as SF₆ or NF₃, a passivation gas such as O₂, HBr or carbonyl sulfide (COS), and a dilute gas such as helium (He), nitrogen (N₂) or argon (Ar). A preferred example includes NF₃ as an etching gas, a O₂ as a passivation gas, and nitrogen (N₂) as a dilute gas.

As aforementioned, the fluorocarbon-free plasma etching chemistry is employed in combination with the plasma pulse output mode as depicted in FIG. 3. By way of example, and briefly referring back to FIGS. 1-3, during the output ON period or etching period t₁ of the period T for one single duty cycle, NF₃ and/or radical substances derived from NF₃ in the plasma etches the semiconductor substrate 10, meanwhile, O2 and/or radical substances derived from O₂ in the plasma slightly oxidizes the trench sidewalls to avoid lateral, isotropic etching. During the output OFF period or passivation period t₂, N₂ and/or radical substances derived from N₂ in the plasma passivate the trench sidewall to keep the trench sidewall profile straight.

Those skilled in the art will readily observe that numerous modifications and alterations of the device and method may be made while retaining the teachings of the invention.

What is claimed is:

1. A method of etching trenches in a semiconductor substrate, comprising:
forming a patterned hard mask over a semiconductor substrate; and
using the patterned hard mask as an etching mask, performing a plasma etching process to etch trenches into the semiconductor substrate not covered by the patterned hard mask, wherein the plasma etching process employs a fluorocarbon-free plasma etching chemistry and is performed under a plasma pulse output mode.

2. The method of etching trenches in a semiconductor substrate according to claim 1 wherein the fluorocarbon-free plasma etching chemistry comprises an etching gas including SF₆ or NF₃, a passivation gas including O₂, HBr or carbonyl sulfide (COS), and a dilute gas including helium (He), nitrogen (N₂) or argon (Ar).

3. The method of etching trenches in a semiconductor substrate according to claim 1 wherein the fluorocarbon-free plasma etching chemistry comprises NF₃, O₂, and N₂.

4. The method of etching trenches in a semiconductor substrate according to claim 1 wherein the plasma pulse output mode comprises a period T of one single duty cycle having an output ON period t₁ and an output OFF period t₂, and thus generating plasma periodically.

5. The method of etching trenches in a semiconductor substrate according to claim 4 wherein a percentage of the output ON period t₁ relative to the period T is in a range from 20% to 80%.

6. The method of etching trenches in a semiconductor substrate according to claim 1 wherein the patterned hard mask comprises a first hard mask layer and a second hard mask layer overlying the first hard mask layer.

7. The method of etching trenches in a semiconductor substrate according to claim 6 wherein the first hard mask layer comprises polysilicon.

8. The method of etching trenches in a semiconductor substrate according to claim 6 wherein the second hard mask layer comprises silicon oxide.
